(19) United States
(12) Patent Application Publication
(10) Pub. No.: US 2019/0393039 A1
(43) Pub. Date: Dec. 26, 2019

(54) METHOD FOR MANUFACTURING CONDUCTIVE PLUG

(71) Applicant: Silergy Semiconductor Technology (Hangzhou) LTD, Hangzhou (CN)

(72) Inventor: Huan Wang, Hangzhou (CN)

(21) Appl. No.: 16/433,250

(22) Filed: Jun. 6, 2019

(30) Foreign Application Priority Data
Jun. 20, 2018 (CN) 201810635997.6

(51) Int. Cl. H01L 21/266; H01L 21/768; H01L 29/417; H01L 29/08

(52) U.S. Cl. CPC H01L 21/266; H01L 21/76802; H01L 29/0847; H01L 29/41725; H01L 21/76877

(57) ABSTRACT

A method can include: providing a substrate comprising a first doping region of a first doping type, and a second doping region of a second doping type, where the first and second doping regions are covered by a dielectric layer; etching the dielectric layer to form a first contact hole partially exposing the first doping region, and a second contact hole partially exposing the second doping region; implanting dopant of the first doping type into the first and second doping regions through the first and second contact holes to increase a surface concentration of the first doping region; and after implanting the dopant, filling the first and second contact holes with conductive material to form conductive plugs.

### RELATED APPLICATIONS

This application claims the benefit of Chinese Patent Application No. 201810635997.6, filed on Jun. 20, 2018, which is incorporated herein by reference in its entirety.

### FIELD OF THE INVENTION

The present invention generally relates to semiconductor devices and processes, and more particularly to methods of manufacturing conductive plugs.

### BACKGROUND

The on-resistance of a circuit may be substantially affected by intrinsic on-resistance and interconnection resistance of the device. After the device has been designed and previous processes have been completed, the value of the intrinsic on-resistance of the device has been determined. Also, the interconnect resistance of subsequent processes can affect the on-resistance of the circuit. Among these factors, the resistivity of the metal is relatively low, and the on-resistance of the circuit can be most affected by the resistance of the contact hole.

### BRIEF DESCRIPTION OF THE DRAWINGS

FIG. 1 is a flow diagram of an example method of manufacturing a conductive plug, in accordance with embodiments of the present invention.

FIGS. 2A-2E are cross-sectional diagrams of various exemplary steps of manufacturing a conductive plug, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that includes pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

In a typical non-metal silicide process, the resistance of a contact hole may be relatively large due to the difficulty in forming a good ohmic contact, particularly when the contact resistance of the P-type active region is relatively large. Due to the influences of surface doping concentration and heat treatment, the distribution of the resistance of the contact hole may not be uniform. In one approach, a contact hole may be formed by an etching process after the previous processes (e.g., including N+/P+ injection, RTA heat treatment, etc.) have completed, and then depositing tungsten metal directly in the contact hole to form an interconnection between previous and subsequent process steps.

In one embodiment, a method can include: (i) providing a substrate comprising a first doping region of a first doping type, and a second doping region of a second doping type, where the first and second doping regions are covered by a dielectric layer; (ii) etching the dielectric layer to form a first contact hole partially exposing the first doping region, and a second contact hole partially exposing the second doping region; (iii) implanting dopant of the first doping type into the first and second doping regions through the first and second contact holes to increase a surface concentration of the first doping region; and (iv) after implanting the dopant, filling the first and second contact holes with conductive material to form conductive plugs.

In one embodiment, a semiconductor structure can include: (i) a substrate; (ii) a first doping region of a first doping type and a second doping region of a second doping type in the substrate; (iii) a patterned dielectric layer on the substrate, and that is configured to selectively expose surfaces of the first and second doping regions; and (iv) conductive plugs on the exposed surfaces of the first and second doping regions, where the doping concentration of the first and second doping regions are not uniform.

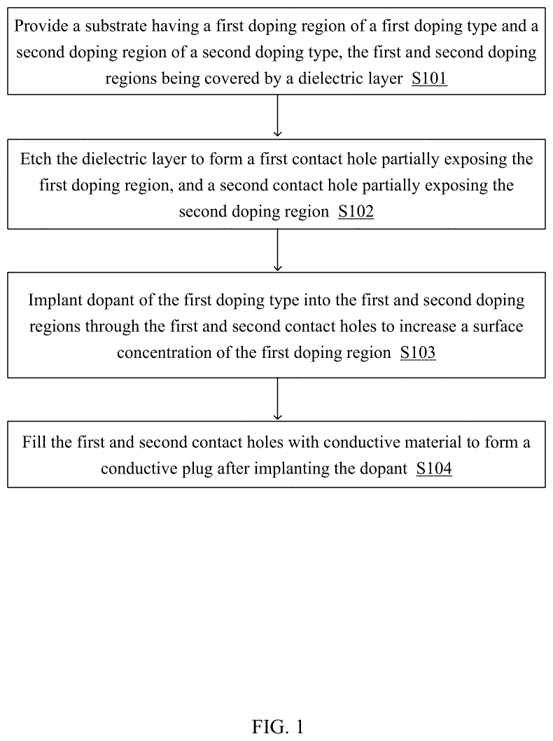

Referring now to FIG. 1, shown is a flow diagram of an example method of manufacturing a conductive plug, in accordance with embodiments of the present invention. In particular embodiments, a method of manufacturing a conductive plug can include, at S101, providing a substrate including a first doping region having a first doping type and a second doping region having a second doping type. The first and second doping regions may be covered by a dielectric layer. At S102, a first contact hole partially exposing the first doping region, and a second contact hole partially exposing the second doping region, may be formed by etching the dielectric layer.

At S103, dopant having a first doping type may be implanted into the first and second doping regions through the first and second contact holes, in order to increase the surface concentration of the first doping region. At S104, the first and second contact holes may be filled with a conductive material to form a conductive plug after implanting the dopant. For example, the influence of the dopant on the surface ions of the second doping region may be reduced by controlling the doping concentration of the dopant without adding a mask.

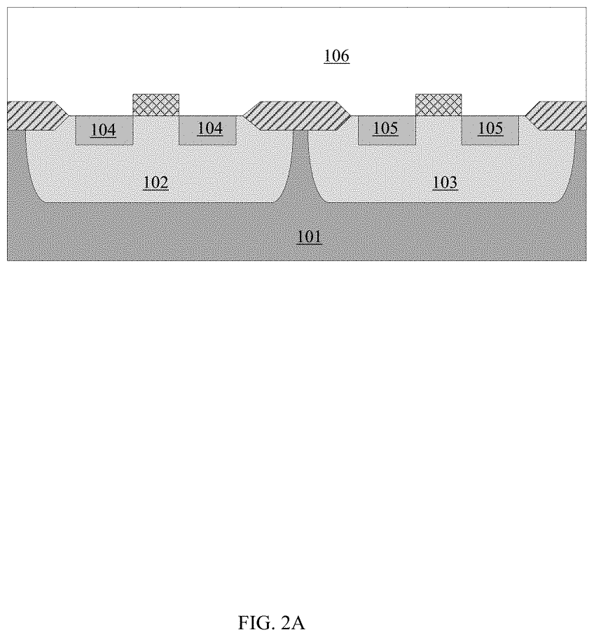

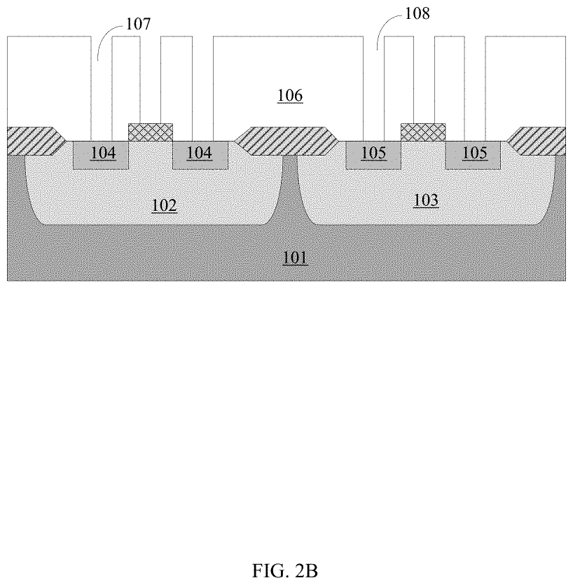

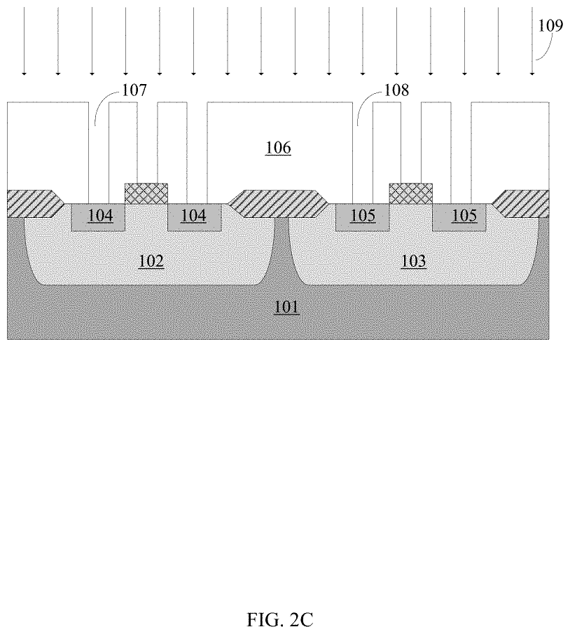

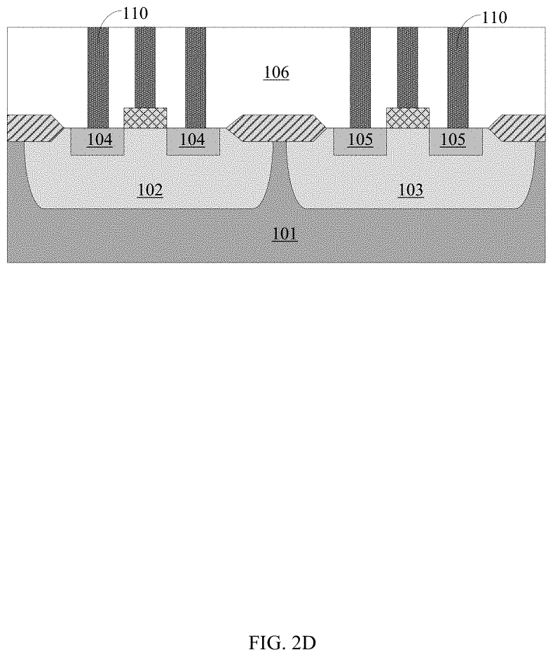

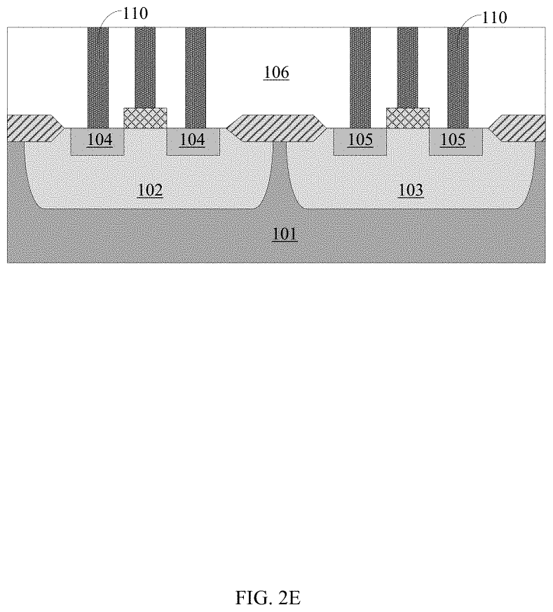

Referring now to FIGS. 2A-2E, shown are cross-sectional diagrams of various exemplary steps of manufacturing a conductive plug, in accordance with embodiments of the present invention. In this particular example, the first doping type can be P-type, the second doping type can be N-type, and the conductive plug may be formed on a surface of drain/source region of a semiconductor device including NMOS and PMOS transistor/devices.

As shown in FIG. 2A, the semiconductor device can include substrate 101, N-type well region 102, and P-type well region 103 formed in substrate 101. In addition, P-type doping region 104 may be formed in well region 102, and N-type doping region 105 can be formed in well region 103. The semiconductor device can also include a field isolation region formed on an upper surface of substrate 101, and a gate dielectric layer and a gate conductor formed on a surface of well region 102 and a surface of well region 103. In this example, doping region 104 can be a P-type drain/source region of the PMOS transistor, and doping region 105 can be an N-type drain/source region of the NMOS transistor. Dielectric layer 106 (e.g., oxide, etc.) having a certain thickness may be deposited on the upper surface of substrate 101 to fully cover well regions 102 and 103.

Subsequently, as shown in FIG. 2B, a portion of dielectric layer 106 may be etched to form contact hole 107 partially exposing the first doping region, and contact hole 108 partially exposing the second doping region. In addition, a third contact hole partially exposing the gate conductor may also be formed by etching dielectric layer 106. In subsequent process step(s), a conductive material may be filled in contact hole 107 in contact with the surface of doping region 104 to form a first contact resistance, and a conductive material may be filled in contact hole 108 in contact with the surface of doping region 105 to form a second contact resistance.

Subsequently, as shown in FIG. 2C, ion implantation process 109 can be performed, and P-type dopant may be implanted into the surface of P-type drain/source region 104 and the surface of N-type drain/source region 105 through contact holes 107 and 108. The dopant can be used to increase the doping concentration of the surface of P-type drain/source region 104, in order to reduce the first contact resistance, such that a good ohmic contact can be formed for subsequent process step(s). The implantation process can control the dose of the P-type dopant in order to reduce its influence on the ions of N-type drain/source region 105; that is, to reduce its influence on the second contact resistance such that the second contact resistance remains substantially constant.

The implantation energy of the P-type dopant may also be controlled such that the implantation depth of the dopant is relatively close to the surface of the first and second doping regions. For example, the larger the doping concentration of the P-type dopant, the smaller the first contact resistance. The doping concentration of the P-type dopant may be controlled to be, e.g., from about 3% to about 20% of the doping concentration of the P-type drain/source region and/or the N-type drain/source region, in order to reduce its influence on the N-type drain/source region ions. In this way, decreases of the first contact resistance may be greater than increases of the second contact resistance. For example, the doping concentration of the P-type dopant can be about 10% of doping concentration of the P-type drain/source region and/or the N-type drain/source region.

The implantation energy of the P-type dopant may be controlled to be, e.g., from about 80% to about 100% of the implantation energy of the P-type drain/source region and/or the N-type drain/source region. For example, the implantation energy of the P-type dopant can be about 80% of the implantation energy of the P-type drain/source region and/or the N-type drain/source region. In particular embodiments, the doping concentration of the P-type dopant can be about 10% of the doping concentration of the P-type drain/source region, which is about 2e14 cm⁻², the dopant may be boron, and the implantation energy can be about 40 Kev. Those skilled in the art will recognize that adjustments can be made to the implantation energy and the doping concentration of dopants corresponding according to contact resistance requirements of the P-type drain/source regions without affecting the contact resistance of the N-type drain/source regions.

An ion implantation process can be performed after forming the contact hole, such that the ion implantation process may only affect the doping concentration of a region under the contact hole and not the overall doping concentration of the device. In this way, the channel concentration of the device may not be affected. In addition, P-type dopant may be implanted in the drain/source regions of the NMOS transistor and the PMOS transistor simultaneously, such that one or two photolithography steps can be reduced without adding a mask. Further, by controlling the dose of the ion implantation, the contact resistance of the PMOS transistor can be significantly reduced, and the contact resistance of the NMOS transistor may be substantially constant, after the step of ion implantation.

As shown in FIG. 2D, after the implantation process has completed, conductive material may be deposited into the first to third contact holes to form conductive plugs 110. For example, a Ti/TiN layer may first be deposited in the contact hole, such that subsequent conductive material may better adhere to the contact hole. Then, the conductive material (e.g., tungsten, aluminum, etc.) can be deposited in the contact hole, and the conductive material on the upper surface of the dielectric layer may be removed, such as by chemical mechanical polishing (CMP), to form conductive plug 110.

Subsequently, as shown in FIG. 2E, a metal layer (e.g., aluminum, etc.) may be deposited on the surface of the dielectric layer and conductive plug 110, and interconnect wires 111 of a source, a gate, and a drain may be formed by partially etching the metal layer. The first doping type may be one of an N type and a P type, and the second doping type may be the other of the N type and the P type.

In particular embodiments, the dopant may be implanted in drain/source regions after forming the contact holes in order to increase the doping concentration of a surface of the drain/source regions, such that a good ohmic contact is formed between the conductive plug and drain/source regions, and the contact resistance is reduced. Further, the implantation process may only affect the region under the contact hole, and not the overall doping concentration of the device. In addition, dopant of the same doping type may be implanted in two different type doping regions, such that one or two lithography process steps can be reduced, and associated process costs (e.g., lithography mask) may not be added. Further, the influence of the implanted dopant on the resistance of doping region with its opposite doping type may be reduced by controlling the doping concentration of the dopant.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method, comprising:
a) providing a substrate comprising a first doping region of a first doping type, and a second doping region of a second doping type, wherein the first and second doping regions are covered by a dielectric layer;
b) etching the dielectric layer to form a first contact hole partially exposing the first doping region, and a second contact hole partially exposing the second doping region;
c) implanting dopant of the first doping type into the first and second doping regions through the first and second contact holes to increase a surface concentration of the first doping region; and
d) after implanting the dopant, filling the first and second contact holes with conductive material to form conductive plugs.

2. The method according to claim 1, wherein the influence of the first dopant on ions of the second doping region is reduced by controlling the doping concentration of the dopant without adding a mask.

3. The method according to claim 1, further comprising forming a first well region having the second doping type and a second well region having the first doping type in the substrate, wherein the first doping region is located in the first well region, and the second doping region is located in the second well region.

4. The method according to claim 1, further comprising, after the filling the first and second contact holes, depositing a metal on the surface of the conductive material and the dielectric layer to form an interconnect wire.

5. The method according to claim 1, wherein the conductive material is in contact with the surface of the first doping region to form a first contact resistance, and the conductive material is in contact with a surface of the second doping region to form a second contact resistance.

6. The method according to claim 5, further comprising controlling the doping concentration of the dopant of the first doping type such that the first contact resistance is decreased and the second contact resistance is substantially constant.

7. The method according to claim 6, wherein the magnitude of the decrease in the first contact resistance is greater than the magnitude of the increase in the second contact resistance.

8. The method according to claim 6, wherein the greater the doping concentration of the dopant of the first doping type, the lower the first contact resistance.

9. The method according to claim 2, wherein doping concentration of the dopant of the first doping type is from 3% to 20% of the doping concentration of the first doping region.

10. The method according to claim 2, wherein doping concentration of the dopant of the first doping type is from 3% to 20% of the doping concentration of the second doping region.

11. The method according to claim 1, wherein the implantation depth of the dopant is close to the surface of the first doping region by controlling the implantation energy of the dopant.

12. The method according to claim 11, wherein the implantation energy of the dopant of the first doping type is from 80% to 100% of the implantation energy of the first doping region.

13. The method according to claim 11, wherein the implantation energy of the dopant of the first doping type is from 80% to 100% of the implantation energy of the second doping region.

14. The method according to claim 1, wherein the conductive material is one of tungsten and aluminum.

15. The method according to claim 1, further comprising before the filling the first and second contact holes, depositing a Ti/TiN layer in the first and second contact holes.

16. The method according to claim 1, wherein the first doping region is a drain/source region of the MOS device.

17. The method according to claim 1, wherein the second doping region is a drain/source region of the MOS device.

18. A semiconductor structure, comprising:
a) a substrate;
b) a first doping region of a first doping type and a second doping region of a second doping type in the substrate;
c) a patterned dielectric layer on the substrate, and that is configured to selectively expose surfaces of the first and second doping regions; and
d) conductive plugs on the exposed surfaces of the first and second doping regions,
e) wherein the doping concentration of the first and second doping regions are not uniform.

19. The semiconductor structure of claim 18, wherein doping concentration of upper surface of the first doping region is greater than that of a lower portion of the first doping region.

20. The semiconductor structure of claim 18, wherein doping concentration of upper surface of the second doping region is lower than that of a lower portion of the first doping region.
